(19) United States
(12) Patent Application Publication
(10) Pub. No.: US 2013/0270589 A1
(43) Pub. Date: Oct. 17, 2013

(54) OPTOELECTRONIC DEVICE WITH NON-CONTINUOUS BACK CONTACTS

(71) Applicants: Brendan M. KAYES, San Francisco, CA (US); Sylvia SPRYUTTE, Palo Alto, CA (US); I-Kang DING, Sunnyvale, CA (US); Rose TWIST, San Jose, CA (US); Gregg HIGASHI, San Jose, CA (US)

(72) Inventors: Brendan M. KAYES, San Francisco, CA (US); Sylvia SPRYUTTE, Palo Alto, CA (US); I-Kang DING, Sunnyvale, CA (US); Rose TWIST, San Jose, CA (US); Gregg HIGASHI, San Jose, CA (US)

(73) Assignee: ALTA DEVICES, INC., Santa Clara, CA (US)

(21) Appl. No.: 13/446,876

(22) Filed: Apr. 13, 2012

(51) Int. Cl. H01L 33/10; H01L 31/0304; H01L 31/0232; H01L 33/22

(52) U.S. Cl. 257/95; 257/184; 257/98; 257/432; 257/E33.068; 257/E31.127; 257/E33.027; 257/E31.022

(57) ABSTRACT

An optoelectronic device is disclosed. The optoelectronic device comprises a semiconductor structure; a plurality of contacts on the front side of the semiconductor structure; and a plurality of non-continuous metal contacts on a back side of the semiconductor structure. In an embodiment, a plurality of non-continuous back contacts on an optoelectronic device improve the reflectivity and reduce the losses associated with the back surface of the device.

### FIELD OF THE INVENTION

The present invention relates generally to optoelectronic devices and more particularly to an optoelectronic device with non-continuous contacts on both the front and the back side.

### BACKGROUND OF THE INVENTION

It is always desirable to improve the reflectivity of the back surface an optoelectronic device such as solar cell to improve the performance thereof without significantly affecting the cost or adding to overall size of the device. Accordingly, there is a need to provide such an improvement while addressing the above identified issues. The present invention addresses such a need.

### SUMMARY OF THE INVENTION

An optoelectronic device is disclosed. The optoelectronic device comprises a semiconductor structure; a plurality of contacts on the front side of the semiconductor structure; and a plurality of non-continuous metal contacts on a back side of the semiconductor structure. In an embodiment, a plurality of non-continuous back contacts on an optoelectronic device improve the reflectivity and reduce the losses associated with the back surface of the device. Specifically, the metal-semiconductor interface of a standard device introduces losses that can be mitigated by reducing the fraction of the area in which metal and semiconductor are in contact. In addition, a device in accordance with the present invention is anticipated to reduce the chance of shunting between the front-side and back-side metallizations, as well potentially improved reliability.

### BRIEF DESCRIPTION OF THE DRAWINGS

The appended drawings illustrate only some embodiments and are therefore not to be considered limiting of scope.

FIG. 1 depicts a first embodiment of a bifacial optoelectronic device.

FIG. 2 depicts a second embodiment of a bifacial optoelectronic device.

FIG. 3 depicts a third embodiment of a bifacial optoelectronic device.

FIG. 4 depicts a fourth embodiment of a bifacial optoelectronic device.

FIG. 5 depicts a fifth embodiment of a bifacial optoelectronic device.

FIG. 6 depicts a sixth embodiment of a bifacial optoelectronic device.

FIG. 7 depicts a first embodiment of an optoelectronic device with a reflector layer.

FIG. 8 depicts a second embodiment of an optoelectronic device with a reflector layer.

FIG. 9 depicts a third embodiment of an optoelectronic device with a reflector layer.

FIG. 10 depicts a fourth embodiment of an optoelectronic device with a reflector layer.

FIG. 11 depicts a first embodiment of an optoelectronic device with multiple pn junctions.

FIG. 12 depicts a second embodiment of an optoelectronic device with multiple pn junctions.

FIG. 13 depicts a third embodiment of an optoelectronic device with multiple pn junctions.

### DETAILED DESCRIPTION

The present invention relates generally to optoelectronic devices and more particularly to an optoelectronic device with non-continuous contacts on both the front and the back side. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

In an embodiment, a plurality of non-continuous back contacts on an optoelectronic device improve the reflectivity and reduce the power losses associated with the configuration of the back surface of the device. In an embodiment, an optoelectronic device can be provided that has non-continuous back contacts. The completed device can be left with both sides able to accept incident light or can be backed by a dielectric and metal reflector to better trap light within the device. By reducing the amount of metal in direct contact with the semiconductor, plasmonic losses at the back contact are reduced, improving the angle-averaged reflectivity of the back contact, which in turn increases the minority carrier density in the device under illumination, improving the external fluorescence of the device and increasing the open-circuit and operating voltages of the device. These features are of particular importance in a photovoltaic cell and for LED applications. Accordingly, described below in conjunction with the accompanying figures are multiple embodiments of an optoelectronic device which utilizes such contacts.

By “non-continuous” it is not necessarily implied that the metal contacts are disconnected. The back metal contacts could be all connected together, or they could be disconnected. It is important merely that they do not cover the entire surface. In the same way, the front metal contacts are non-continuous yet connected, in that they do not cover the entire front surface of the device (which would block the incident sunlight in the case of a solar cell, or the exiting light in the case of an LED), and yet are connected such that power can be input or extracted by making contact to a single point on the top metal of the device (as well as making connection to the back of the device).

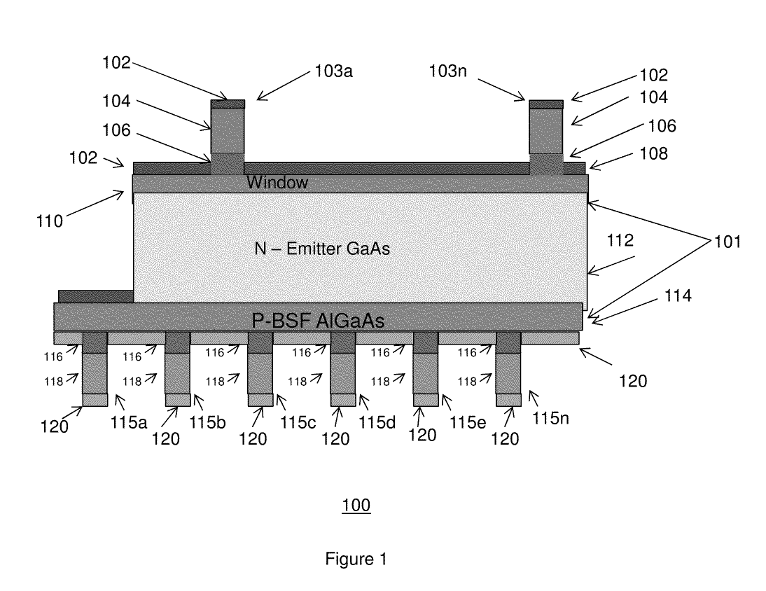

FIG. 1 depicts a first embodiment of a bifacial optoelectronic device 100. The device 100 includes a semiconductor structure 101. In an embodiment, the semiconductor structure 101 comprises an N-layer 112 and P-layer 114 coupled together. For example, the N-layer is an N-emitter GaAs layer 112 and the P-layer is a P-BSF (Back Surface Field) AlGaAs layer 114. However one of ordinary skill in the art readily recognizes a variety of materials including but not limited to GaAs, AlGaAs, InGaP, InGaAs, and alloys thereof, etc., could be utilized for either of these layers and that would be within the spirit and scope of the present invention. Furthermore, the junction formed between the two layers does not have to be a heterojunction, that is, both the N-layer 112 and P-Layer 114 could be the same material (both layers being GaAs or both layers AlGaAs, for example) and that would be within the spirit and scope of the present invention. Also the doping could be inverted, with p-type material at the top of the device, facing the sun, and n-type material at the bottom. Furthermore, the optoelectronic device could be comprised of multiple p-n layers grown in series, for example to form a multijunction solar cell.

In this embodiment, on a top side of the semiconductor structure 101 are a plurality of contact member's 103a-103n. Each of the top-side contact members 103a-103n comprise an optional antireflective coating (ARC) 102, a n-metal contact 104 underneath the optional ARC 102, and a gallium arsenic (GaAs) contact 106 underneath the n-metal contact. A window layer 110 is preferably on top of the semiconductor structure 101. The optional ARC layer 102 is also in contact with the window layer 110, and possibly the p-type material 114. On a back side of the semiconductor structure 101 is a plurality of non-continuous contacts 115a-115n. Each of the non-continuous contacts 115 includes an optional contact layer 116 coupled to the back side of the semiconductor structure 101 and a P-metal contact 118 underneath contact layer 116. An optional ARC layer 120 may also be present on the back side of the device.

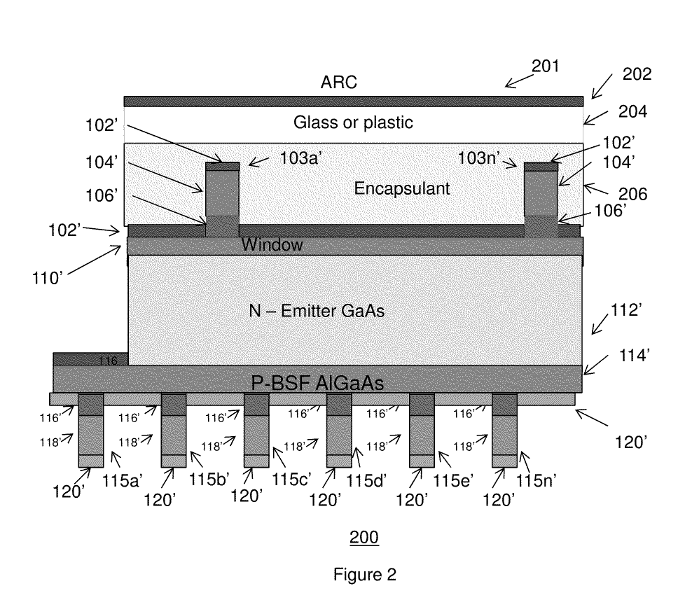

FIG. 2 depicts a second embodiment of a bifacial optoelectronic device 200. Optoelectronic device 200 is substantially the same as optoelectronic device 100, except it includes a top side layer 201. The top side layer 201 comprises an optional second ARC 202, a transparent member 204, such as glass or plastic, underneath the second ARC 202 and an encapsulant 206 which is underneath the glass layer 204. The encapsulant 206 surrounds the top side contacts 103a′-103n′.

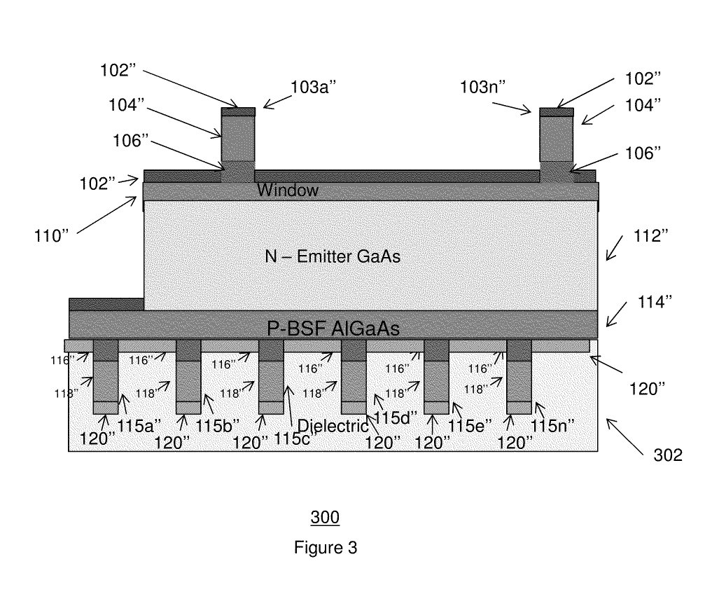

FIG. 3 depicts a third embodiment of a bifacial optoelectronic device 300. Optoelectronic device 300 is substantially the same as optoelectronic device 100, except it includes a dielectric 302 which encapsulates the bottom side contacts 115a″-115n″.

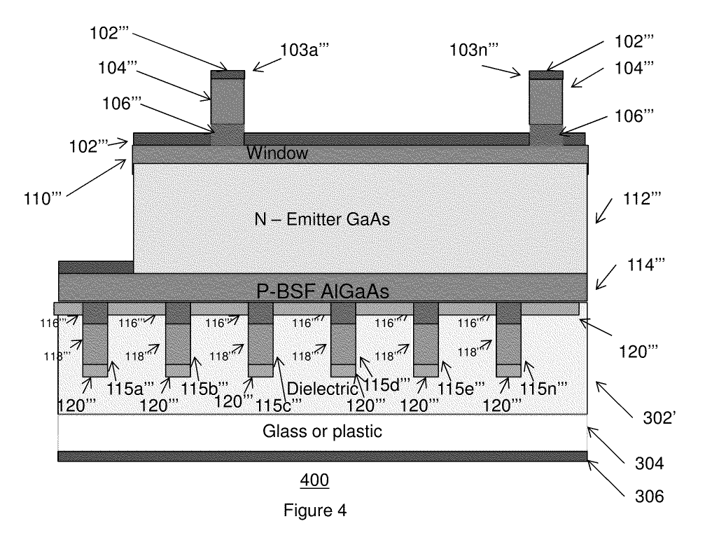

FIG. 4 depicts a fourth embodiment of a bifacial optoelectronic device 400. Optoelectronic device 400 is substantially the same as optoelectronic device 300, except it includes a back side support transparent member 304, and an optional ARC layer 306. In embodiments, the transparent member 304 could be for example a glass or plastic layer.

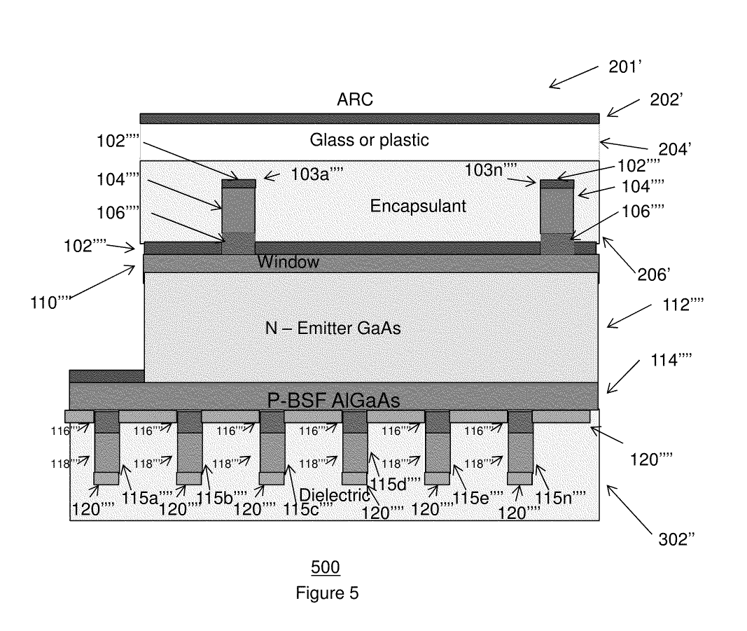

FIG. 5 depicts a fifth embodiment of a bifacial optoelectronic device 500. Optoelectronic device 500 is substantially the same as optoelectronic device 300, except it includes the top side layer 201′ as described in FIG. 2.

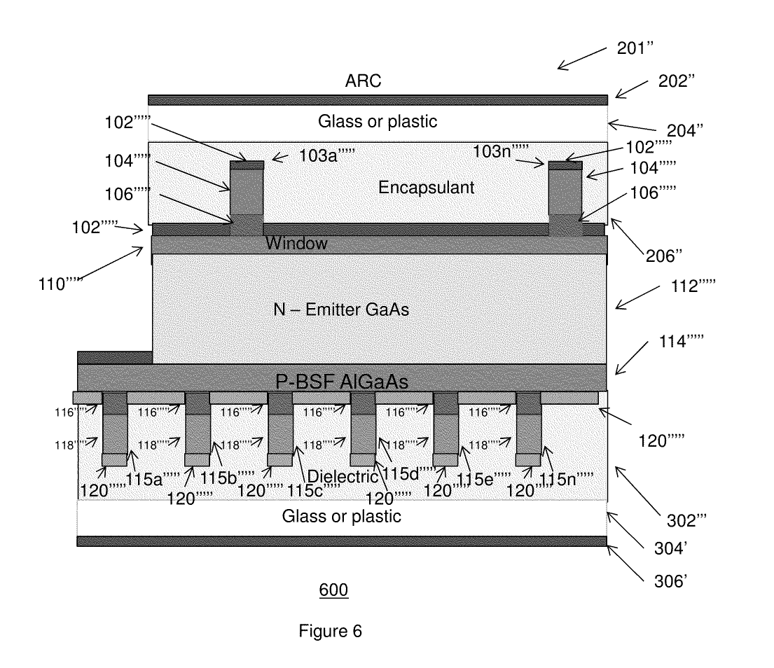

FIG. 6 depicts a sixth embodiment of a bifacial optoelectronic device 600. Optoelectronic device 600 is substantially the same as optoelectronic device 500, except it includes a back side support transparent member 304′, and an optional ARC layer 306′.

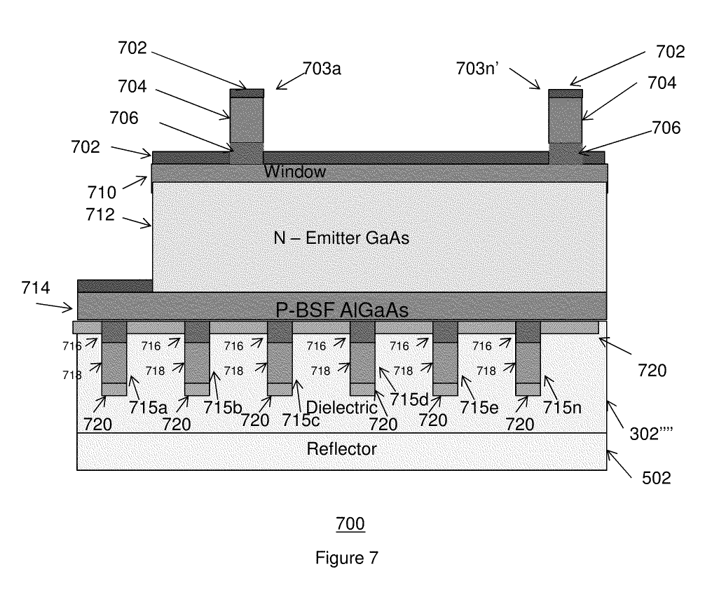

FIG. 7 depicts a first embodiment of an optoelectronic device 700 with a reflector layer. Optoelectronic device 700 is substantially similar to optoelectronic device 300, except it includes a reflector layer 502 which is in contact with the dielectric 302″″. Typically the reflector layer 502 will be a highly reflective metal such as silver, gold, copper, or aluminum, or an alloy of one or more of these with either other metals in the list, or with other materials not on the list. The reflector layer 502 should be in a preferred embodiment a good conductor of electricity.

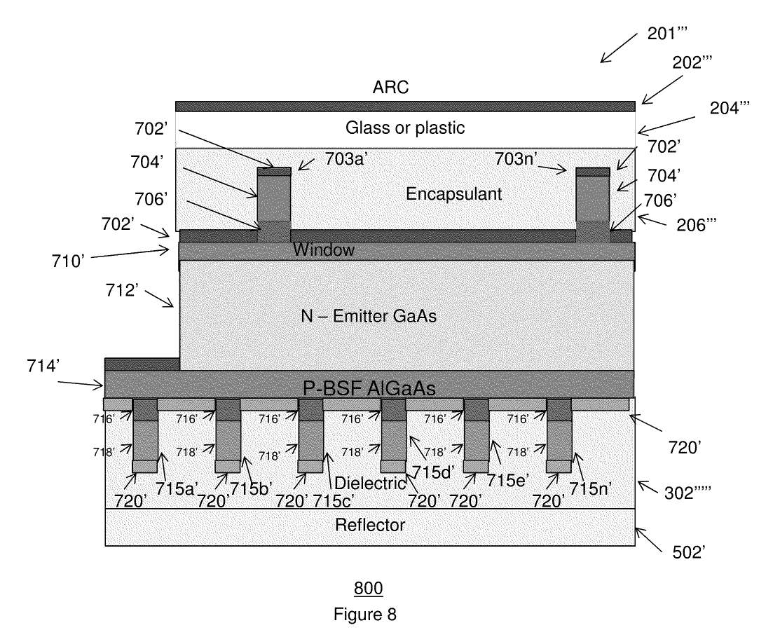

FIG. 8 depicts a second embodiment of an optoelectronic device 800 with a reflector layer. Optoelectronic device 800 is substantially the same as optoelectronic device 500, except it includes a reflector layer 502′ on the bottom side.

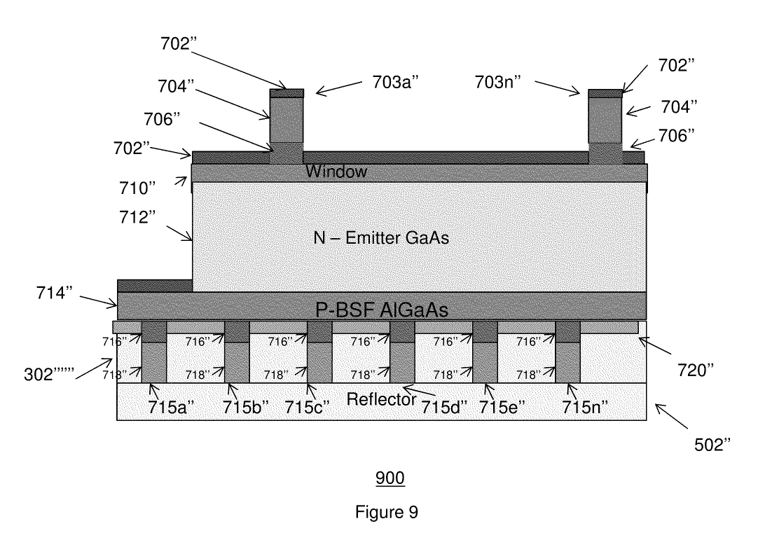

FIG. 9 depicts a third embodiment of an optoelectronic device 900 with a reflector layer. Optoelectronic device 900 is substantially the same as optoelectronic device 700, except that the reflector layer 502″ is electrically coupled to the back side contacts 715a″-715n″.

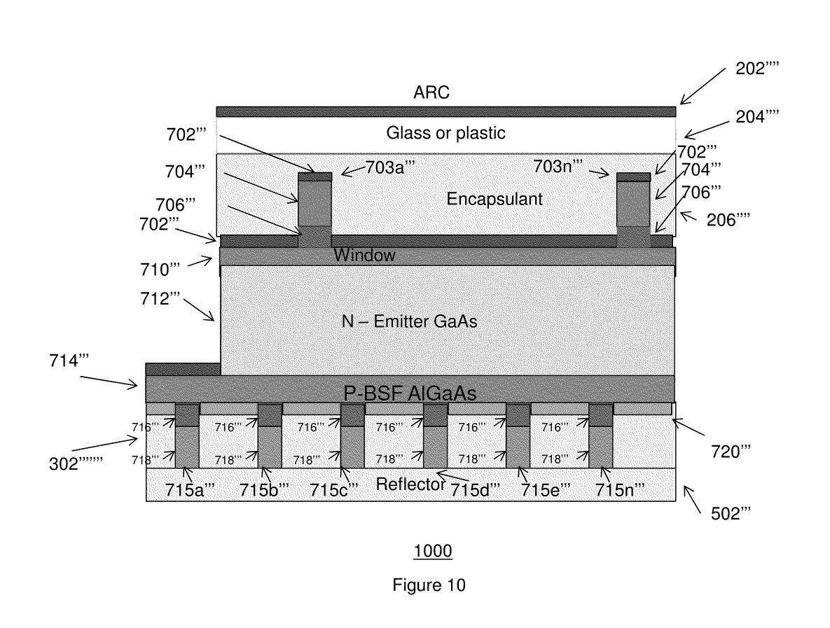

FIG. 10 depicts a fourth embodiment of an optoelectronic device 1000 with a reflector layer. Optoelectronic device 1000 is substantially similar to optoelectronic device 800, except that the reflector layer 502″═ is electrically coupled to the back side contacts 715a″′-715n″′.

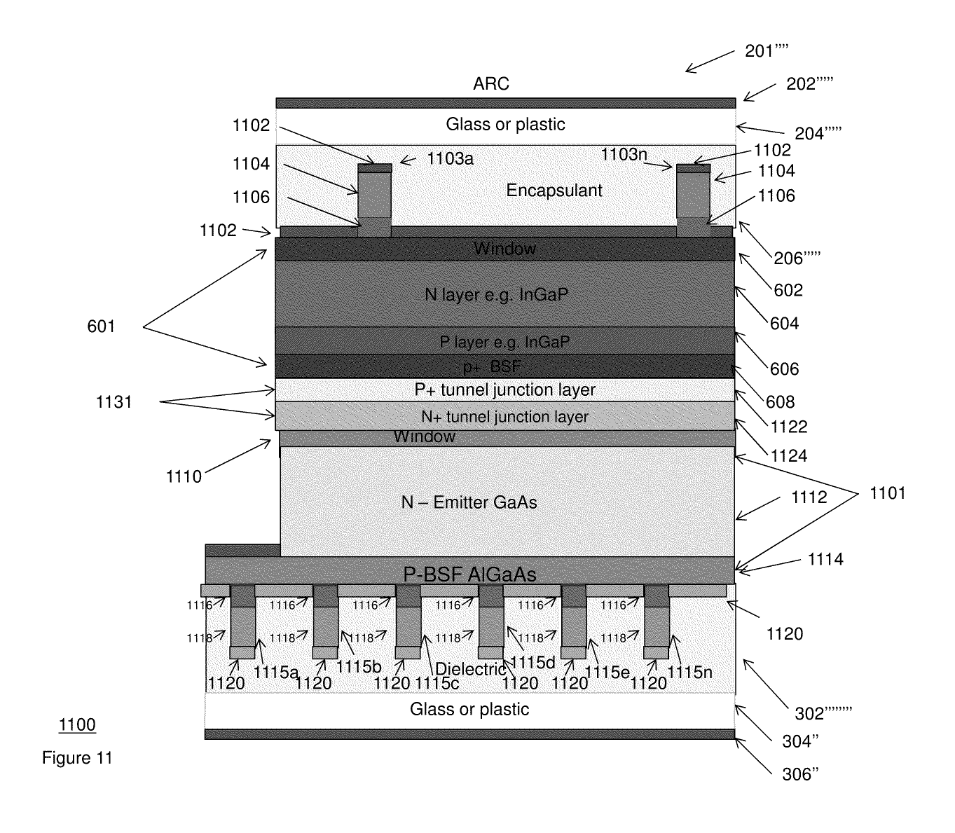

FIG. 11 depicts a first embodiment of an optoelectronic device 1100 with multiple pn junctions. Optoelectronic device 1100 is substantially similar to optoelectronic device 600, except that an additional pn junction structure 601 of higher bandgap has been added above structure 1101. Structure 601 is comprised of a window layer 602 (for example AlInP, AlGaInP, or AlGaAs), an n-type material 604 (for example InGaP or AlGaAs), a p-type material 606 (for example InGaP or AlGaAs), and back-surface field or back side window layer 608 (for example AlInP, AlGaInP, or AlGaAs). This structure is electrically and optically connected to structure 1101 through a tunnel junction structure 1131. Structure 1131 is comprised of a highly p-type doped layer 1122 (for example InGaP or AlGaAs), and a highly n-type doped layer 1124 (for example InGaP or AlGaAs).

One of ordinary skill in the art readily recognizes a variety of materials listed could differ from the examples listed herein. Furthermore, the pn junction formed in structure 601 could be a homojunction or a heterojunction that is, both the N-layer 604 and P-Layer 606 could be the same material, or could be different materials, and that would be within the spirit and scope of the present invention. Also the doping could be inverted, with p-type material at the top of the device, facing the sun, and n-type material at the bottom. One or more additional pn structures could be added to structure 1101 in a similar fashion, either above or below structure 1101, and possibly coupled to the rest of the device through a tunnel junction layer or layers.

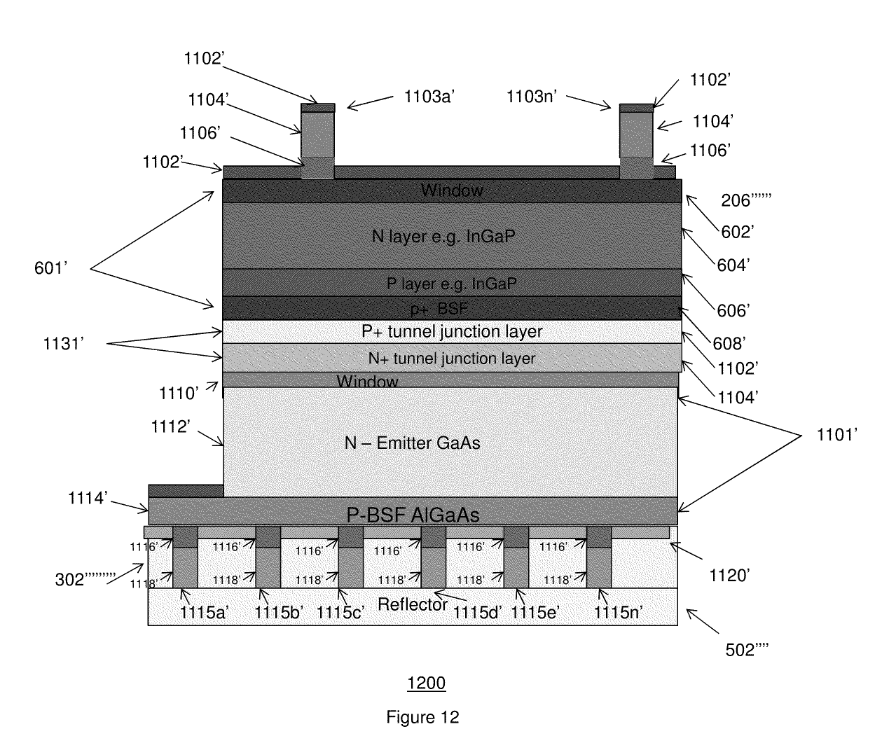

FIG. 12 depicts a second embodiment of an optoelectronic device 1200 with multiple pn junctions. Optoelectronic device 1200 is substantially similar to optoelectronic device 900, except that an additional pn junction structure 601′ of higher bandgap has been added above structure 1101′, with the structures coupled through a tunnel junction structure 1131′, as described above for FIG. 11.

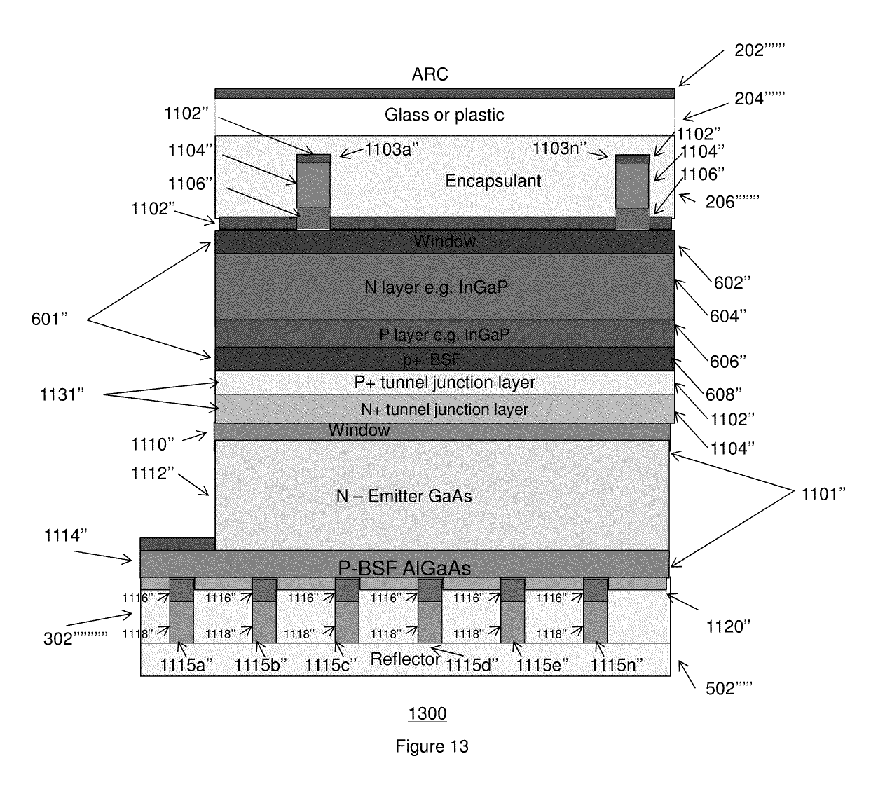

FIG. 13 depicts a third embodiment of an optoelectronic device 1300 with multiple pn junctions. Optoelectronic device 1300 is substantially similar to optoelectronic device 1000, except that an additional pn junction structure 601″ of higher bandgap has been added above structure 1101″, with the structures coupled through a tunnel junction structure 1131″, as described above for FIG. 11.

In all of the above identified embodiments a plurality of non-continuous back contacts on an optoelectronic device improve the reflectivity and reduce the losses associated with the back surface of the device, for example plasmonic losses at a metal-semiconductor interface. By adding enhancements such as a dielectric material, back side reflector and the like, the reflectivity can also be improved in some applications. In addition, in an embodiment the back side and/or the front side of the semiconductor can be textured to improve light scattering into and/or out of the device. Finally, it is well understood by those of ordinary skill in the art that additional layers could exist either on top of the structures shown, or underneath them. For example, underneath the reflector metal there could be other support layers such as metals, polymers, glasses, or any combination thereof.

The non-continuous metal contacts in any of the above mentioned embodiments can be arranged such that there is never alignment (in the sense of an imaginary perpendicular line drawn directly through the cell) between the contacts on the top of the device and the plurality of non-continuous metal contacts directly adjacent to the semiconductor structure material on the back of the device. In some embodiments, there may still be alignment between the front metal and the back mirror metal, but there will be a dielectric between them. In other embodiments there is no back mirror metal. In either case, this can provide an additional advantage in that the chance of a metal-on-metal short, either during device fabrication or after the device has aged, can be greatly reduced. This can improve manufacturing yield and product reliability.

### Advantages

1. Allows for bifacial design where both sides of device can be illuminated.

2. Decouples electrical and optical functions of back surface of optoelectronic device.

3. Reduced losses of the back contact.

4. Improved reflectivity of the back contact

5. Reduced dark current, improving device performance

6. Reduced chance of device shunting, improving dark current of device as well as yield and reliability.

Although the present invention has been described in accordance with the embodiments shown, one of ordinary skill in the art will readily recognize that there could be variations to the embodiments and those variations would be within the spirit and scope of the present invention. For example, the metal contacts on either the front side and/or the back side of a device can be replaced by a highly conductive yet transparent or semi-transparent layer, for example a transparent conductive oxide and that would be within the spirit and scope of the present invention. Accordingly, many modifications may be made by one of ordinary skill in the art without departing from the spirit and scope of the appended claims.

What is claimed is:

1. An optoelectronic device comprising:
a semiconductor structure;
a plurality of contacts on a top side of the semiconductor layer; and
a plurality of non-continuous metal contacts on a back side of the semiconductor structure.

2. The optoelectronic device of claim 1, wherein a dielectric material surrounds the plurality of non-continuous metal contacts.

3. The optoelectronic device of claim 1, wherein the plurality of non-continuous metal contacts are offset from the top contacts.

4. The optoelectronic device of claim 2, wherein a reflector covers the dielectric material.

5. The optoelectronic device of claim 4, wherein the reflector is electrically coupled to the non-continuous metal contacts, allowing electrical current to flow from the device through the non-continuous metal contacts and into the reflector.

6. The optoelectronic device of claim 1, wherein the semiconductor structure comprises a p-n layer.

7. The optoelectronic device of claim 6, wherein the p-n structure comprises a N-emitter GaAs layer and a P-AlGaAs layer in contact with each other.

8. The optoelectronic device of claim 1, wherein the semiconductor structure comprises multiple p-n layers.

9. The optoelectronic device of claim 1, wherein the back side and/or the front side of the semiconductor is textured to improve light scattering into and/or out of the device.

10. The optoelectronic device of claim 1, wherein a reflector covers the plurality of non-continuous metal contacts.

11. The optoelectronic device of claim 1, which includes a top side layer, the top side layer comprising an encapsulant for the top side contacts, and a transparent member on top of the encapsulant.

12. The optoelectronic device of claim 11, which includes an anti-reflective coating on top of the transparent member.

13. The optoelectronic device of claim 11, wherein a dielectric material surrounds the plurality of non-continuous metal contacts.

14. The optoelectronic device of claim 11, wherein a reflector covers the plurality of metal contacts.

15. The optoelectronic device of claim 11, wherein a dielectric material surrounds the plurality of non-continuous metal contacts and a reflector covers the dielectric material.

16. The optoelectronic device of claim 15, wherein the reflector is electrically coupled to the non-continuous back-metal contacts, allowing electrical current to flow from the device through the contacts and into the reflector metal.

17. The optoelectronic device of claim 11, which includes a back side layer, the back side layer comprising an encapsulant for the back side contacts, and a transparent member behind the encapsulant.

18. The optoelectronic device of claim 11, wherein the semiconductor structure comprises a p-n layer.

19. The optoelectronic device of claim 18, wherein the p-n structure comprises a N-emitter GaAs layer and a P-AlGaAs layer in contact with each other.

20. The optoelectronic device of claim 11, wherein the semiconductor structure comprises multiple p-n layers.

21. The optoelectronic device of claim 11, wherein the back side and/or the front side of the semiconductor is textured to improve light scattering into and/or out of the device.

22. An optoelectronic device comprising:
a p-n structure;
a plurality of contacts on a top side of the p-n structure; and
a plurality of non-continuous metal contacts on the back side of the p-n structure.

23. The optoelectronic device of claim 22, wherein the plurality of non-continuous metal contacts are offset from the top contacts.

24. The optoelectronic device of claim 22, which includes a dielectric material surrounding the plurality of non-continuous metal contacts.

25. The optoelectronic device of claim 24, wherein a reflector covers the dielectric material.

26. The optoelectronic device of claim 25, wherein the reflector is electrically coupled to the non-continuous metal contacts, allowing electrical current to flow from the device through the contacts and into the reflector.

27. The optoelectronic device of claim 22, wherein the back side and/or the front side of the semiconductor is textured to improve light scattering into and/or out of the device.
